(19) United States
(12) Patent Application Publication
(10) Pub. No.: US 2026/0312565 A1
(43) Pub. Date: Oct. 8, 2026

(54) MULTIPLEXER

(71) Applicant: Murata Manufacturing Co., Ltd., Nagaokakyo-shi (JP)

(72) Inventor: Ryosuke NAKAHATA, Nagaokakyo-shi (JP)

(21) Appl. No.: 19/632,701

(22) Filed: Mar. 30, 2026

(30) Foreign Application Priority Data
Apr. 4, 2025 (JP) 2025-062579

(51) Int. Cl. H03H 9/25; H03H 9/02; H03H 9/145; H03H 9/64; H03H 9/72; H04B 1/00

(52) U.S. Cl. CPC H03H 9/25; H03H 9/02559; H03H 9/145; H03H 9/6483; H03H 9/72; H04B 1/0057

(57) ABSTRACT

A multiplexer includes an acoustic wave filter having a first passband and a filter having a second passband. A center frequency fc2 of the second passband is greater than or equal to about 1.35 times a center frequency fc1 of the first passband. In the acoustic wave filter, a first acoustic wave resonator connected closest to a common terminal includes a piezoelectric substrate, an IDT electrode including multiple electrode fingers, and an insulating layer including the IDT electrode embedded therein. When λ denotes a wavelength of the IDT electrode and t denotes a film thickness of the insulating layer, (t/λ)×100≤20.124×(fc2/fc1)²−92.823×(fc2/fc1)+119.41 is satisfied.

### CROSS REFERENCE TO RELATED APPLICATIONS

This application claims the benefit of priority to Japanese Patent Application No. 2025-062579 filed on Apr. 4, 2025. The entire contents of this application are hereby incorporated herein by reference.

### BACKGROUND OF THE INVENTION

### 1. Field of the Invention

The present invention relates to multiplexers.

### 2. Description of the Related Art

Japanese Unexamined Patent Application Publication No. 2017-220929 discloses a multiplexer including a first filter and a second filter. The first filter is connected to a common contact and includes a surface acoustic wave (SAW) filter and a SAW resonator. The second filter is connected to the common contact. Japanese Unexamined Patent Application Publication No. 2017-220929 states that spurious signals occurring within the passband of the second filter can be reduced by making the thickness of a dielectric film covering the SAW filter greater than that of a dielectric film covering the SAW resonator.

### SUMMARY OF THE INVENTION

With the advancement of high-capacity and multi-band mobile communication, there is a growing demand for multiplexers capable of performing simultaneous low-loss communication of signals in multiple bands with separated frequencies.

Accordingly, example embodiments of the present invention provide multiplexers each capable of performing simultaneous low-loss communication of signals in multiple bands separated in frequency.

According to an example embodiment of the present invention, a multiplexer includes a common terminal, an acoustic wave filter, and a first filter. The acoustic wave filter is connected to the common terminal and has a first passband including at least a portion of a first band. The first filter is connected to the common terminal and has a second passband including at least a portion of a second band. A center frequency of the second passband is at least about 1.35 times a center frequency of the first passband. The acoustic wave filter includes multiple acoustic wave resonators. Among the multiple acoustic wave resonators, a first acoustic wave resonator connected closest to the common terminal includes a piezoelectric substrate including a first main surface and including lithium niobate, an IDT (interdigital transducer) electrode on the first main surface and including multiple first electrode fingers, multiple second electrode fingers, a first busbar electrode connecting first ends of the multiple first electrode fingers, and a second busbar electrode connecting first ends of the multiple second electrode fingers, and an insulating layer on the first main surface and disposed with the IDT electrode embedded therein. In the first acoustic wave resonator, a relational formula (t/λ)×100≤20.124×(fc2/fc1)²−92.823×(fc2/fc1)+119.41 is satisfied, where λ denotes a wavelength of the IDT electrode including the multiple first electrode fingers or the multiple second electrode fingers, t denotes a film thickness of the insulating layer in a region between adjacent electrode fingers among the multiple first electrode fingers and multiple second electrode fingers, fc1 denotes the center frequency of the first passband, and fc2 denotes the center frequency of the second passband.

According to example embodiments of the present invention, multiplexers each are capable of simultaneous low-loss communication of signals of multiple bands separated in frequency.

The above and other elements, features, steps, characteristics and advantages of the present invention will become more apparent from the following detailed description of the example embodiments with reference to the attached drawings.

### BRIEF DESCRIPTION OF THE DRAWINGS

FIG. 1 is a circuit configuration diagram of a multiplexer according to an example embodiment of the present invention.

FIG. 2 is a diagram illustrating the frequency relationship between filters included in a multiplexer according to an example embodiment of the present invention.

FIGS. 3A and 3B are plan views and cross-sectional views of a first acoustic wave resonator according to an example embodiment of the present invention.

FIG. 4 is a cross-sectional view of a first acoustic wave resonator according to a modification of an example embodiment of the present invention.

FIG. 5 is a graph showing the reflection characteristics of an acoustic wave filter according to an example embodiment of the present invention.

FIG. 6 is a graph showing the relationship between the center frequency ratio of a multiplexer and the film thickness-to-wavelength ratio of a first acoustic wave resonator according to an example embodiment of the present invention.

### DETAILED DESCRIPTION OF THE EXAMPLE EMBODIMENTS

Hereinafter, example embodiments of the present disclosure will be described in detail using the drawings. The example embodiments described hereafter each illustrate a comprehensive or specific example of the present invention. The numerical values, shapes, materials, components, arrangement of the component, the ways in which the components are connected to each other and so forth given in the following example embodiments are merely examples and are not intended to limit the present invention.

The drawings are schematic diagrams in which certain elements are emphasized or omitted or their proportions are adjusted as appropriate in order to illustrate example embodiments of the present invention, the drawings are not necessarily illustrated in a strictly accurate manner, and the actual shapes, positional relationships, and proportions may be different. In the drawings, configurations that are substantially the same as each other may be denoted by the same symbols and repeated description thereof may be omitted or simplified.

In addition, terms indicating the relationships between elements, such as “parallel” and “perpendicular”, terms indicating the shape of elements such as “rectangular”, and numerical ranges do not express only a strict meaning, but rather are intended to include substantially equivalent ranges, for example, differences of several percent.

In the present disclosure, the pass band of an acoustic wave device or an acoustic wave filter is defined as the frequency band between two frequencies that are 3 dB above the minimum insertion loss within that passband.

Furthermore, in the resonance characteristics of an acoustic wave device according to an example embodiment of the present disclosure, the resonant frequency and anti-resonant frequency are derived, for example, by contacting RF probes to the two input/output terminals of the acoustic wave device while the acoustic wave device is not connected to other circuit elements, and measuring the reflection characteristics (impedance characteristics) using a network analyzer or the like.

Furthermore, in the present disclosure, “main component of a material” refers to a component that constitutes more than 50% by weight of the material. Such a main component may exist in either a single-crystal, polycrystalline, or amorphous state, or in a mixture of these states.

Furthermore, in the present disclosure, “band” refers to at least one of an uplink operation band and a downlink operation band within a frequency band predefined by standardization bodies etc. (e.g., 3GPP (registered trademark), IEEE (Institute of Electrical and Electronics Engineers), etc.) for communication systems constructed using Radio Access Technology (RAT). In this example embodiment, the communication system may employ, for example, an LTE (Long Term Evolution) system, a 5G (fifth Generation)—NR (New Radio) system, and a WLAN (Wireless Local Area Network) system, but is not limited to these systems. The uplink operation band of a frequency band refers to the frequency range within that band designated for uplink use. Furthermore, the downlink operation band of a frequency band refers to the frequency range within that band designated for downlink use.

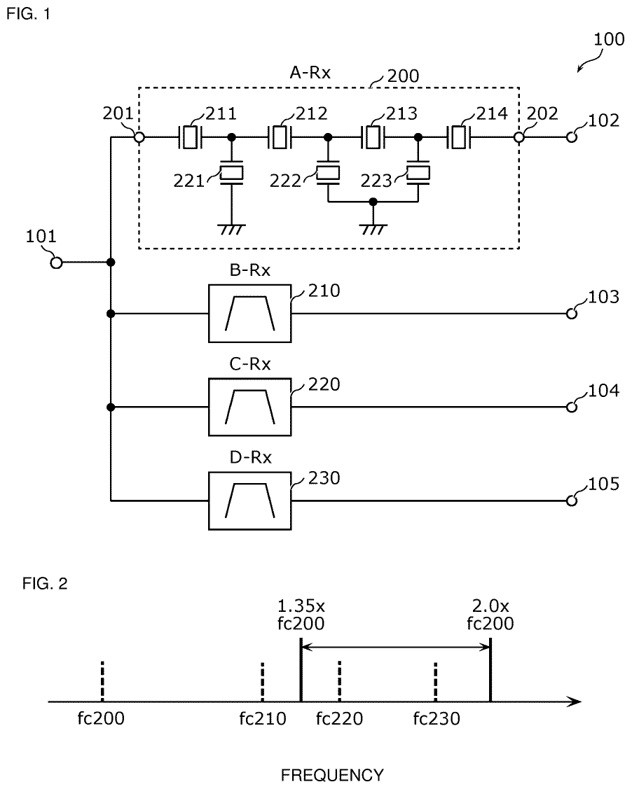

An example circuit configuration of a multiplexer 100 according to an example embodiment will be described. FIG. 1 is a circuit configuration diagram of the multiplexer 100 according to the present example embodiment. As illustrated in the figure, the multiplexer 100 includes an acoustic wave filter 200, filters 210, 220, and 230, a common terminal 101, and input/output terminals 102, 103, 104, and 105. The common terminal 101 is connected to an antenna, for example.

The acoustic wave filter 200 is connected between the common terminal 101 and the input/output terminal 102 and has a first passband including at least a portion of Band A (first band). The first passband includes a reception band (A-Rx) of Band A, for example. The acoustic wave filter 200 is a ladder bandpass filter that includes series arm resonators 211, 212, 213, and 214, parallel arm resonators 221, 222, and 223, and input/output terminals 201 and 202. Each of the series arm resonators 211 to 214 and the parallel arm resonators 221 to 223 is an acoustic wave resonator. The detailed structure of the series arm resonators 211 to 214 and the parallel arm resonators 221 to 223 will be described later. Note that the acoustic wave filter 200 does not need to be a ladder bandpass filter, and may be, for example, an acoustic wave filter including longitudinally coupled resonators.

The series arm resonators 211 to 214 are disposed in series along a series arm path connecting the input/output terminals 201 and 202 to each other, in the order of the series arm resonators 211, 212, 213, and 214, from the input/output terminal 201 toward the input/output terminal 202. The series arm resonator 211 is an example of a first acoustic wave resonator and is the acoustic wave resonator connected closest to the common terminal 101 among the multiple acoustic wave resonators constituting the acoustic wave filter 200. The parallel arm resonator 221 is connected between a connection node between the series arm resonators 211 and 212, and ground. The parallel arm resonator 222 is connected between a connection node between the series arm resonators 212 and 213, and ground. The parallel arm resonator 223 is connected between a connection node between the series arm resonators 213 and 214, and ground.

Note that the acoustic wave filter 200 is not limited to a ladder filter including four series arm resonators and three parallel arm resonators. The acoustic wave filter 200 may be a ladder filter including one or more series arm resonators and one or more parallel arm resonators. Furthermore, the first acoustic wave resonator, which is connected closest to the common terminal 101 among the multiple acoustic wave resonators included in the acoustic wave filter 200, may be a parallel arm resonator.

The filter 210 is connected between the common terminal 101 and the input/output terminal 103, and has a third passband that includes at least a portion of Band B. The third passband includes a reception band (B-Rx) of Band B, for example. The filter 210 may be an acoustic wave filter, or alternatively, may be an LC filter, a dielectric filter, or the like. The structure of the filter is arbitrary.

The filter 220 is connected between the common terminal 101 and the input/output terminal 104, and has a fourth passband that includes at least a portion of Band C. The fourth passband includes a reception band (C-Rx) of Band C, for example. The filter 220 may be an acoustic wave filter, or alternatively, may be an LC filter, a dielectric filter, or the like. The structure of the filter is arbitrary.

The filter 230 is an example of a first filter, is connected between the common terminal 101 and the input/output terminal 105, and has a second passband that includes at least a portion of Band D (second band), for example. The second passband includes a reception band (D-Rx) of Band D, for example. The filter 230 may be an acoustic wave filter, or alternatively, may be an LC filter, a dielectric filter, or the like. The structure of the filter is arbitrary.

Furthermore, the filters 210 and 220 do not need to be included in the multiplexer 100, and it is sufficient that the number of filters included in the multiplexer 100 be two or more filters, including the acoustic wave filter 200 and the filter 230.

In addition, at least one of the acoustic wave filter 200 and the filters 210 to 230 may be a transmission filter having a passband that includes a transmission band.

FIG. 2 is a diagram illustrating the frequency relationship between the filters constituting the multiplexer 100 according to the present example embodiment. A center frequency fc220 of the fourth passband of the filter 220 and a center frequency fc230 of the second passband of the filter 230 are each positioned in a frequency range greater than or equal to about 1.35 times and less than or equal to twice a center frequency fc200 of the first passband of the acoustic wave filter 200, for example. Furthermore, the center frequency fc220 of the fourth passband and the center frequency fc230 of the second passband are preferably each positioned within a frequency range greater than about 1.4 times the center frequency fc200 of the first passband, for example. Note that the center frequency fc220 does not need to be positioned within a frequency range that is greater than or equal to about 1.35 times and less than or equal to about twice the center frequency fc200, for example.

In this example embodiment, Band A (first band) is a composite band including, for example, bands n75 and n76 for 5G-NR. Additionally, Band B (second band) is, for example, band B3 for LTE or band n3 for 5G-NR. Additionally, Band C is, for example, band B1 for LTE or band n1 for 5G-NR. Additionally, Band D is, for example, band B7 for LTE or band n7 for 5G-NR.

The structure of the series arm resonators 211 to 214 and the parallel arm resonators 221 to 223 of the acoustic wave filter 200 will be described.

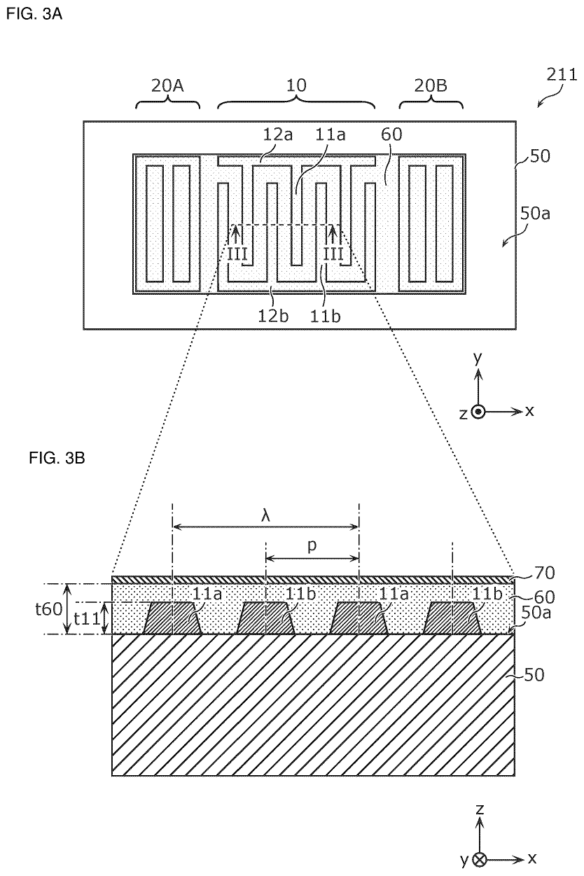

FIGS. 3A and 3B depict a plan view and a cross-sectional view of the series arm resonator 211 according to an example embodiment. FIG. 3A is a plan view of a main surface 50a of a piezoelectric substrate 50 (looking through an insulating layer 60) from the positive z-axis side. FIG. 3B is a cross-sectional view taken along line III-III in FIG. 3A. As illustrated in FIGS. 3A and 3B, the series arm resonator 211 includes an IDT electrode 10, reflection electrodes 20A and 20B, the piezoelectric substrate 50, the insulating layer 60, and a dielectric layer 70.

The IDT electrode 10 is disposed on the main surface 50a of the piezoelectric substrate 50. As illustrated in FIG. 3A, the IDT electrode 10 includes multiple electrode fingers 11a and multiple electrode fingers 11b, as well as busbar electrodes 12a and 12b.

The multiple electrode fingers 11a are an example of multiple first electrode fingers and are positioned parallel or substantially parallel to each other. The multiple electrode fingers 11b are an example of multiple second electrode fingers and are positioned parallel or substantially parallel to each other. The multiple electrode fingers 11a and multiple electrode fingers 11b are positioned parallel or substantially parallel to each other in an interdigitated manner. The busbar electrode 12a is an example of a first busbar electrode, and is disposed to connect first ends of the multiple electrode fingers 11a to each other. The busbar electrode 12a extends in a direction (x-axis direction) intersecting the extension direction (y-axis direction) of the multiple electrode fingers 11a. The busbar electrode 12b is an example of a second busbar electrode, and is disposed to connect first ends of the multiple electrode fingers 11b to each other. The busbar electrode 12b extends in a direction (x-axis direction) intersecting the extension direction (y-axis direction) of the multiple electrode fingers 11b. The busbar electrode 12a and the busbar electrode 12b are disposed to face each other with the multiple electrode fingers 11a and multiple electrode fingers 11b interposed therebetween. Second ends of the multiple electrode fingers 11a face the busbar electrode 12b and second ends of the multiple electrode fingers 11b face the busbar electrode 12a.

The reflection electrodes 20A and 20B are disposed on both sides of the IDT electrode 10, so as to be adjacent to the IDT electrode 10, in a direction (x-axis direction) perpendicular to the extension direction of electrode fingers 11a and 11b. Note that at least one of the reflection electrodes 20A and 20B does not need to be disposed on either side of the IDT electrode 10.

The IDT electrode 10 and the reflection electrodes 20A and 20B may each have a configuration including a metal or alloy, for example, Ti, Al, Cu, Pt, Au, Ag, or Pd, or may include multiple multilayer bodies including such metals or alloys.

Next, a wavelength λ of the IDT electrode 10 will be explained. The wavelength λ of the IDT electrode 10 is a unit of length defined by the repeating period of the electrode fingers 11a or 11b. An electrode finger pitch p of the IDT electrode 10 is about ½ the wavelength λ. Furthermore, in the IDT electrode 10, when the spacing between adjacent electrode fingers is not constant, the wavelength λ of the IDT electrode 10 is defined as an average wavelength λ_{AVE} of the IDT electrode 10. The average wavelength λ_{AVE} of the IDT electrode 10 is defined as 2×Di/(Ni−1), where Ni is the total number of electrode fingers 11a and 11b included in the IDT electrode 10, and Di is the center-to-center distance between the electrode finger that is positioned at one end of the IDT electrode 10 and the electrode finger that is positioned at the other end of the IDT electrode 10 in the propagation direction of acoustic waves.

Furthermore, in the case where the IDT electrode 10 includes so-called thinned out electrodes, when the average wavelength λ_{AVE} is calculated, the number of thinned out electrodes should be excluded from the total number of electrode fingers Ni, and a line width L of the thinned out electrodes and one of the two adjacent spaces (space width S) should be excluded from the center-to-center distance Di. Note that the term thinned out electrodes includes floating thinned out electrodes, polarity reversal electrodes, and filling electrodes. A floating thinned out electrode is an electrode finger that is not connected to either of the two opposing busbar electrodes, and is positioned parallel or substantially parallel to electrode fingers connected to one of the two busbar electrodes. A polarity reversal electrode is an electrode finger connected to the same busbar electrode as the busbar electrode to which both adjacent electrode fingers are connected, and positioned parallel or substantially parallel to both adjacent electrode fingers. A filling electrode is an electrode finger that has an electrode finger width of at least twice the average electrode finger width of the electrode fingers excluding the filling electrodes, and is positioned parallel or substantially parallel to the electrode fingers excluding the filling electrodes.

The wavelength λ of the IDT electrode 10 is measured using a scanning electron microscope (SEM), a scanning transmission electron microscope (STEM), or a transmission electron microscope (TEM). The measurement is performed by measuring the line width and space width by viewing the main surface 50a of the piezoelectric substrate 50, on which the IDT electrode 10 is formed, in plan view, and/or by viewing a cross-section perpendicular to the extension direction of the electrode fingers 11a and 11b.

The piezoelectric substrate 50 is an example of a piezoelectric substrate, includes the main surface 50a (first main surface), and includes a piezoelectric single crystal. The piezoelectric substrate 50 is a single-crystal piezoelectric substrate, for example, including lithium niobate. The piezoelectric substrate 50 may also be a single-crystal piezoelectric substrate including lithium tantalate, quartz, or potassium nitride.

The insulating layer 60 is disposed on the main surface 50a and is disposed such that the IDT electrode 10 is embedded therein. More specifically, the insulating layer 60 is disposed on the main surface 50a so as to cover the upper surfaces of the electrode fingers 11a and 11b of the IDT electrode 10, and such that, in the regions between the electrode fingers 11a and the electrode fingers 11b, a film thickness t60 thereof is greater than or equal to about 90% of a film thickness t11 of the electrode fingers 11a and 11b, for example. The insulating layer 60 is a layer for example having silicon dioxide (SiO₂) as a main component. Spurious signals occurring on the low-frequency side and high-frequency side of the resonance band of the series arm resonator 211 can be reduced by adjusting the film thickness t60 of the insulating layer 60.

Furthermore, the insulating layer 60 is preferably disposed on the main surface 50a such that the film thickness t60 of the insulating layer 60 in the regions between the electrode fingers 11a and 11b is at least as large as the film thickness t11 of the electrode fingers 11a and 11b.

The dielectric layer 70 is disposed so as to cover the insulating layer 60. The dielectric layer 70 is preferably a layer in which the acoustic velocity of propagating bulk waves is higher than that of bulk waves propagating through the piezoelectric substrate 50. For example, silicon nitride (SiN) or a material having silicon nitride as a main component may be used.

Furthermore, each of the series arm resonators 212 to 214 and the parallel arm resonators 221 to 223 may also have substantially the same structure as the series arm resonator 211 described above, except for the electrode parameters of the IDT electrode 10 (wavelength λ, number of pairs of electrode fingers, electrode finger duty, crossing width, etc.) and the film thickness t60 of the insulating layer 60. In this case, the series arm resonators 211 to 214 and the parallel arm resonators 221 to 223 may be provided on a common piezoelectric substrate 50.

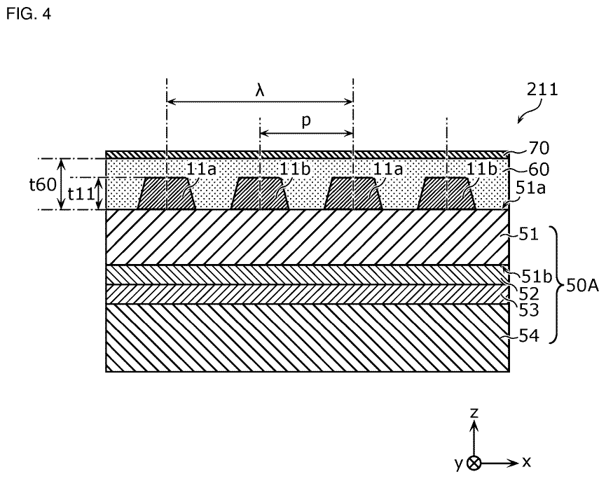

Furthermore, in the series arm resonators 211 to 214 and the parallel arm resonators 221 to 223, the piezoelectric substrate 50 may have a multilayer structure including a piezoelectric layer, an intermediate layer, and a support substrate. FIG. 4 is a cross-sectional view of the series arm resonator 211 according to a modification of the above example embodiments. The series arm resonator 211 according to this modification includes an IDT electrode 10 (illustrated in FIG. 4 as electrode fingers 11a and 11b), reflection electrodes 20A and 20B (not illustrated in FIG. 4), a piezoelectric substrate 50A, an insulating layer 60, and a dielectric layer 70. The series arm resonator 211 of this modification differs from the series arm resonator 211 of the above example embodiments only in terms of the structure of the piezoelectric substrate 50A. Hereinafter, in the description of the series arm resonator 211 according to this modification, descriptions of configurations identical to those of the series arm resonator 211 according to the above example embodiments are omitted, and the focus is on the piezoelectric substrate 50A, which has a different configuration.

As illustrated in FIG. 4, the piezoelectric substrate 50A exhibits piezoelectricity, and includes a piezoelectric layer 51, a low-acoustic-velocity layer 52, a high-acoustic-velocity layer 53, and a support substrate 54.

The piezoelectric layer 51 includes a main surface 51a (first main surface) and a main surface 51b, which face each other. The IDT electrode 10, and the reflection electrodes 20A and 20B are disposed on the main surface 51a. For example, lithium niobate or a material having this material as a main component may be used for the piezoelectric layer 51. The piezoelectric layer 51 may also have lithium tantalate, quartz, or potassium nitride as a main component.

The support substrate 54 is disposed on the main surface 51b side of the piezoelectric layer 51, and supports the piezoelectric layer 51, the IDT electrode 10, and the reflection electrodes 20A and 20B. The support substrate 54 may include, for example, a non-oxide material, such as silicon (Si), silicon carbide (SiC), or a material having any of these materials as a main component. Silicon and silicon carbide exhibit high thermal conductivity, and therefore using these materials as the support substrate 54 enhances the heat dissipation performance of the series arm resonator 211.

The low-acoustic-velocity layer 52 is disposed between the piezoelectric layer 51 and the support substrate 54, and is a layer in which the acoustic velocity of propagating bulk waves is lower than that of bulk waves propagating through the piezoelectric layer 51. For example, silicon oxide (e.g., silicon dioxide) or a material having silicon oxide as a main component may be used as the low-acoustic-velocity layer 52.

In addition, materials used for the low-acoustic-velocity layer 52 may include, for example, dielectric materials such as glass, silicon oxide, silicon nitride, lithium oxide, tantalum oxide, or compounds of silicon oxide with added fluorine, carbon, or boron, or materials having the aforementioned materials as a main component.

The high-acoustic-velocity layer 53 is disposed between the low-acoustic-velocity layer 52 and the support substrate 54, and is a layer in which the acoustic velocity of propagating bulk waves is higher than that of bulk waves propagating through the piezoelectric layer 51. For example, silicon nitride (SiN) or a material having silicon nitride as a main component may be used as the high-acoustic-velocity layer 53.

Furthermore, materials used for the high-acoustic-velocity layer 53 may include, for example, ceramics such as aluminum nitride (AlN), silicon nitride (SiN), zirconia, cordierite, mullite, steatite, forsterite, spinel, and sialon, dielectrics such as aluminum oxide, silicon nitride, diamond-like carbon (DLC), and diamond, or materials having any of the above materials as a main component. Spinel mentioned above includes aluminum compounds containing oxygen and one or more elements selected from Mg, Fe, Zn, Mn, etc. Examples of spinel include MgAl2O₄, FeAl₂O4, ZnAl₂O₄, and MnAl₂O₄.

With the series arm resonator 211 according to the modification, it is possible to increase the Q value at both the resonant frequency and the anti-resonant frequency compared to an acoustic wave resonator using a single-layer piezoelectric substrate. That is, since an acoustic wave resonator with a high Q value can be provided, a filter with low insertion loss can be constructed using this acoustic wave resonator.

Furthermore, each of the series arm resonators 212 to 214 and the parallel arm resonators 221 to 223 may also have substantially the same structure as the series arm resonator 211 according to the modification, except for the electrode parameters (wavelength λ, number of pairs of electrode fingers, electrode finger duty, crossing width, etc.) of the IDT electrode 10 and the film thickness of the insulating layer 60. In this case, the series arm resonators 211 to 214 and the parallel arm resonators 221 to 223 may be formed on a common piezoelectric substrate 50A.

Next, the film thickness range of the insulating layer 60 of the acoustic wave filter 200 that reduces return loss in the second passband and fourth passband will be described.

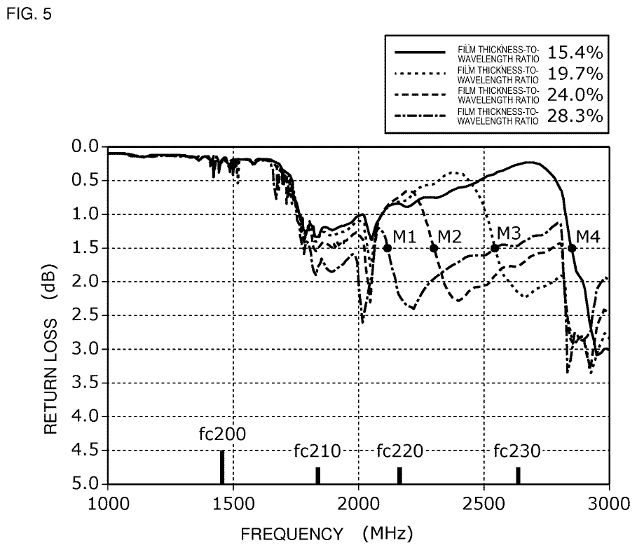

FIG. 5 is a graph illustrating the reflection characteristics of the acoustic wave filter 200 according to the present example embodiment. The vertical axis in the figure represents return loss at the input/output terminal 201 of the acoustic wave filter 200 as a standalone unit. Furthermore, the film thickness-to-wavelength ratio (%) illustrated in the same figure is the ratio of the film thickness t60 of the insulating layer 60 to the wavelength λ of the series arm resonator 211 ((t60/λ)×100).

As illustrated in FIG. 5, the return loss increases in the band on the high-frequency side of the center frequency fc200 of the acoustic wave filter 200. When the film thickness-to-wavelength ratio is about 28.3%, the frequency ratio (frequency relative to fc200) at point M1 where reflection loss is about 1.5 dB is about 1.42, for example. When the film thickness-to-wavelength ratio is about 24.0%, the frequency ratio at point M2 where return loss is about 1.5 dB is about 1.53, for example. When the film thickness-to-wavelength ratio is about 19.7%, the frequency ratio at point M3 where the reflection loss is about 1.5 dB is about 1.71, for example. When the film thickness-to-wavelength ratio is about 15.4%, the frequency ratio at point M4 where the return loss is about 1.5 dB is about 1.92, for example. In other words, the band where the return loss is about 1.5 dB or less expands toward higher frequencies as the film thickness-to-wavelength ratio decreases, for example.

For the filters 220 and 230, which have center frequencies in a range of about 1.35 times to twice that of fc 200, approximately one-third of the return loss (dB) of the acoustic wave filter 200 at fc220 and fc230 is added to the insertion loss in the passbands of the filters 220 and 230, for example. From this perspective, when the acoustic wave filter 200 and at least one of the filters 220 and 230 simultaneously receive signals, the insertion loss in the passband of that one filter needs to be degraded by about 0.5 dB or less compared to when that one filter by itself receives a signal, for example. In other words, the return loss (maximum value thereof) at fc220 and fc230 for the acoustic wave filter 200 preferably is about 1.5 dB or less, for example.

From FIG. 5, for a filter carrying out simultaneous reception along with the acoustic wave filter 200, it is desirable that the higher the center frequency of the other reception filter is relative to fc200, the smaller the film thickness-to-wavelength ratio of the acoustic wave filter 200 is.

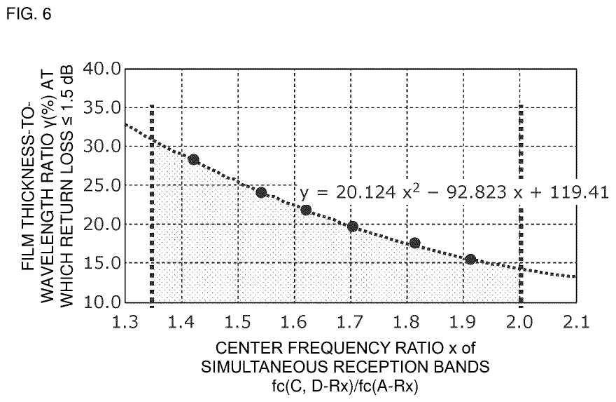

FIG. 6 is a graph illustrating the relationship between a center frequency ratio x of the multiplexer 100 according to the present example embodiment and a film thickness-to-wavelength ratio y (%) of the series arm resonator 211. More specifically, the horizontal axis represents the center frequency ratio x (about 1.35 to about 2.0, for example) of the filter carrying out simultaneous reception with the acoustic wave filter 200. For example, the center frequency ratio between the reception filter 220 and the acoustic wave filter 200 (fc220/fc200=about 1.45) and the center frequency ratio between the filter 230 and acoustic wave filter 200 (fc230/fc200=about 1.80) are included. The vertical axis illustrates the film thickness-to-wavelength ratio y (%) at which the return loss of the acoustic wave filter 200 is about 1.5 dB, for example. In FIG. 6, the relationship between the center frequency ratio x and the film thickness-to-wavelength ratio (%) y, obtained from the reflection characteristics of the series arm resonator 211 illustrated in FIG. 5, is plotted (black dots). An approximation of these plot points is represented by Formula 1.

$$y = 20.124 \times {x}^{2} - 92. 823 \times x + 119.41 ( 1.35 \leq x \leq 2. 0 ) \qquad ( Formula 1 )$$

Formula 1 represents the film thickness-to-wavelength ratio (%) at which the return loss of the acoustic wave filter 200 is about 1.5 dB, when the center frequency ratio x lies in the range of about 1.35 or more and about 2.0 or less, for example. The film thickness-to-wavelength ratio (%) y (=(t60/λ)×100) at which the return loss of the acoustic wave filter 200 becomes, for example, about 1.5 dB or less is represented by Formula 2, where fc1 is the center frequency of the acoustic wave filter 200 and fc2 is the center frequency of the reception filter carrying out simultaneous reception with the acoustic wave filter 200.

$$( t 60 / λ ) \times 100 \leq 20.124 \times {( fc 2 / fc 1 )}^{2} - 92.823 \times ( fc 2 / fc 1 ) + 119.41 \qquad ( Formula 2 )$$

Thus, the multiplexer 100 can be provided that is capable of performing low-loss simultaneous communication using the acoustic wave filter 200 and at least one of the filters 220 and 230, whose frequencies are separated from that of the acoustic wave filter 200 toward the higher frequency side, by defining the film thickness t60 of the insulating layer 60 of the first acoustic wave resonator most closely connected to the common terminal 101 of the acoustic wave filter 200 in accordance with the above Formula 2.

The reflection characteristics of the first acoustic wave resonator connected closest to the common terminal 101 have the greatest influence on the bandpass characteristics of the filters 210, 220, and 230 among the multiple acoustic wave resonators of the acoustic wave filter 200. Therefore, by specifying the film thickness t60 of the insulating layer 60 of the first acoustic wave resonator in accordance with the above Formula 2, degradation of the insertion loss of at least one of the filters 220 and 230 can be more effectively reduced or prevented.

Furthermore, in the series arm resonator 211, the film thickness t60 of the insulating layer 60 is preferably greater than the film thickness t11 of the electrode fingers 11a and 11b. Accordingly, spurious signals on both the low-frequency side and the high-frequency side of the first passband of the acoustic wave filter 200 can be broadly reduced or prevented.

Furthermore, not only the series arm resonator 211, but also each of all the acoustic wave resonators (series arm resonators 211 to 214 and parallel arm resonators 221 to 223) of the acoustic wave filter 200 may satisfy the relational formula defined in Formula 2.

Accordingly, the return loss in bands with center frequency ratios of about 1.35 to about 2.0, for example, in the acoustic wave filter 200 can be further reduced.

In this case, it is also desirable that the film thickness t60 of the insulating layer 60 be greater than the film thickness t11 of the electrode fingers 11a and 11b in each of all the acoustic wave resonators (series arm resonators 211 to 214 and parallel arm resonators 221 to 223) of the acoustic wave filter 200. Accordingly, spurious signals on both the low-frequency side and the high-frequency side of the first passband of the acoustic wave filter 200 can be more broadly reduced or prevented.

As described above, the multiplexer 100 according to an example embodiment includes the common terminal 101, the acoustic wave filter 200 connected to the common terminal 101 and having the first passband that includes at least a portion of the first band, and the filter 230 connected to the common terminal 101 and having the second passband that includes at least a portion of the second band. The center frequency fc2 of the second passband is at least about 1.35 times the center frequency fc1 of the first passband, for example. The acoustic wave filter 200 includes multiple acoustic wave resonators. The first acoustic wave resonator connected closest to the common terminal 101, among the multiple acoustic wave resonators, includes the piezoelectric substrate 50 including the main surface 50a and including lithium niobate, the IDT electrode 10 on the main surface 50a and including multiple electrode fingers 11a, multiple electrode fingers 11b, the busbar electrode 12a connecting first ends of the multiple electrode fingers 11a to each other, and the busbar electrode 12b connecting first ends of the multiple electrode fingers 11b to each other, and the insulating layer 60 on the main surface 50a and including the IDT electrode 10 embedded therein. In the first acoustic wave resonator, when λ is the wavelength of the IDT electrode 10 including the multiple electrode fingers 11a or the multiple electrode fingers 11b, and t is the film thickness of the insulating layer 60 in a region between adjacent electrode fingers among the multiple electrode fingers 11a and the multiple electrode fingers 11b: (t/λ)×100≤20.124×(fc2/fc1)²−92.823×(fc2/fc1)+119.41 (Formula 3) is satisfied.

Thus, the multiplexer 100 can be provided that is capable of performing simultaneous low-loss communication using the acoustic wave filter 200 and the filter 230, whose frequency is separated toward the higher frequency side by a center frequency ratio of about 1.35 times or more relative to the acoustic wave filter 200, by specifying a film thickness t of the insulating layer 60 in accordance with the above Formula 3.

For example, in the multiplexer 100, in the first acoustic wave resonator, the film thickness t of the insulating layer 60 in a region between adjacent electrode fingers among the multiple electrode fingers 11a and the multiple electrode fingers 11b is greater than the film thickness t11 of the multiple electrode fingers 11a and the multiple electrode fingers 11b.

Accordingly, spurious signals on both the low-frequency side and the high-frequency side of the first passband of the acoustic wave filter 200 can be broadly reduced or prevented.

For example, in the multiplexer 100, each of the multiple acoustic wave resonators of the acoustic wave filter 200 includes the piezoelectric substrate 50 including the main surface 50a and including lithium niobate, the IDT electrode 10 on the main surface 50a and including multiple electrode fingers 11a, multiple electrode fingers 11b, the busbar electrode 12a connecting first ends of the multiple electrode fingers 11a to each other and the busbar electrode 12b connecting first ends of the multiple electrode fingers 11b to each other, and the insulating layer 60 on the main surface 50a and including the IDT electrode 10 embedded therein. In each of the multiple acoustic wave resonators, when λ is the wavelength of the IDT electrode 10 including the multiple electrode fingers 11a or the multiple electrode fingers 11b, and t is the film thickness of the insulating layer 60 in a region between adjacent electrode fingers among the multiple electrode fingers 11a and the multiple electrode fingers 11b, the relational formula expressed as Formula 3 is satisfied.

Accordingly, the return loss in a band with a center frequency ratio of about 1.35 or higher, for example, in the acoustic wave filter 200 can be further reduced.

For example, in the multiplexer 100, in each of the multiple acoustic wave resonators, the film thickness t of the insulating layer 60 in a region between adjacent electrode fingers among the multiple electrode fingers 11a and the multiple electrode fingers 11b is greater than the thickness t11 of the multiple electrode fingers 11a and the multiple electrode fingers 11b.

Accordingly, spurious signals on both the low-frequency side and the high-frequency side of the first passband of the acoustic wave filter 200 can be more broadly reduced or prevented.

For example, in multiplexer 100, the center frequency fc2 of the second passband is less than or equal to twice the center frequency fc1 of the first passband.

Accordingly, by specifying the film thickness t of the insulating layer 60 in accordance with Formula 3, it is possible to reduce the return loss in the band with a center frequency ratio of about 1.35 or more and about 2 or less, for example.

For example, in multiplexer 100, the piezoelectric substrate 50 is a single-crystal piezoelectric substrate including lithium niobate.

Accordingly, by adjusting the film thickness t of the insulating layer 60, spurious signals on both the low-frequency and high-frequency sides of the resonance band of the first acoustic wave resonator can be reduced, and furthermore the frequency-temperature characteristics of the first acoustic wave resonator can be improved.

For example, in the multiplexer according to a modification of an example embodiment of the present invention, the piezoelectric substrate 50A includes the piezoelectric layer 51 including the mutually opposing main surfaces 51a and 51b, the support substrate 54 on the main surface 51b side of the piezoelectric layer 51, the low-acoustic-velocity layer 52 between the piezoelectric layer 51 and the support substrate 54 and having a lower bulk wave acoustic velocity than the piezoelectric layer 51 and the support substrate 54, and the high-acoustic-velocity layer 53 between the low-acoustic-velocity layer 52 and the support substrate 54 and having a higher bulk wave acoustic velocity than the low-acoustic-velocity layer 52.

Thus, it is possible to increase the Q value at both the resonant frequency and the anti-resonant frequency compared to acoustic wave resonators using a single-layer piezoelectric substrate. That is, since a first acoustic wave resonator with a high Q value can be configured, it becomes possible to construct a filter with low insertion loss using the first acoustic wave resonator.

For example, in the multiplexer 100, the first band includes at least one of band n75 and band n76 for 5G-NR.

For example, in the multiplexer 100, the second band is band B1, band B3, or band B7 for LTE, or band n1, n3, or n7 for 5G-NR.

Multiplexers according to example embodiments and modifications thereof of the present invention have been described above, but the present invention is not limited to the above example embodiments and modifications. Other example embodiments realized by combining any of the components of the above-described example embodiments and modifications obtained by modifying the above-described example embodiments and modifications in various ways without departing from the spirit of the present invention are also included in the scope of the present invention.

Example embodiments of the present invention can be widely used in communication devices such as mobile phones as a multiplexer in a front end module.

While example embodiments of the present invention have been described above, it is to be understood that variations and modifications will be apparent to those skilled in the art without departing from the scope and spirit of the present invention. The scope of the present invention, therefore, is to be determined solely by the following claims.

What is claimed is:

1. A multiplexer comprising:
a common terminal;
an acoustic wave filter connected to the common terminal and having a first passband including at least a portion of a first band; and
a first filter connected to the common terminal and having a second passband including at least a portion of a second band;
wherein a center frequency fc2 of the second passband is greater than or equal to at least about 1.35 times a center frequency fc1 of the first passband;
the acoustic wave filter includes multiple acoustic wave resonators;
a first acoustic wave resonator connected closest to the common terminal, among the multiple acoustic wave resonators, includes:
a piezoelectric substrate including a first main surface and including lithium niobate;
an IDT electrode on the first main surface and including multiple first electrode fingers, multiple second electrode fingers, a first busbar electrode connecting first ends of the multiple first electrode fingers to each other, and a second busbar electrode connecting first ends of the multiple second electrode fingers to each other; and
an insulating layer on the first main surface and including the IDT electrode embedded therein; and
in the first acoustic wave resonator, when λ denotes a wavelength of the IDT electrode including the multiple first electrode fingers or the multiple second electrode fingers, and t denotes a film thickness of the insulating layer in a region between adjacent electrode fingers among the multiple first electrode fingers and multiple second electrode fingers:
$$( t / λ ) \times 100 \leq 20.124 \times {( fc 2 / fc 1 )}^{2} - 92.823 \times ( fc 2 / fc 1 ) + 11 9.41$$
is satisfied.

2. The multiplexer according to claim 1, wherein in the first acoustic wave resonator, the film thickness of the insulating layer in the region between adjacent electrode fingers among the multiple first electrode fingers and the multiple second electrode fingers is greater than a film thickness of the multiple first electrode fingers and the multiple second electrode fingers.

3. The multiplexer according to claim 1, wherein the multiple acoustic wave resonators each include:
a piezoelectric substrate including a first main surface and including lithium niobate;
an IDT electrode on the first main surface and including multiple first electrode fingers, multiple second electrode fingers, a first busbar electrode connecting first ends of the multiple first electrode fingers to each other, and a second busbar electrode connecting first ends of the multiple second electrode fingers to each other; and
an insulating layer on the first main surface and including the IDT electrode embedded therein; and
in each of the multiple acoustic wave resonators, when λ denotes a wavelength of the IDT electrode including the multiple first electrode fingers or the multiple second electrode fingers, and t denotes a film thickness of the insulating layer in a region between adjacent electrode fingers among the multiple first electrode fingers and multiple second electrode fingers:
$$( t / λ ) \times 100 \leq 20.124 \times {( fc 2 / fc 1 )}^{2} - 92.823 \times ( fc 2 / fc 1 ) + 11 9.41$$
is satisfied.

4. The multiplexer according to claim 3, wherein in each of the multiple acoustic wave resonators, the film thickness of the insulating layer in the region between adjacent electrode fingers among the multiple first electrode fingers and the multiple second electrode fingers is greater than a film thickness of the multiple first electrode fingers and the multiple second electrode fingers.

5. The multiplexer according to claim 1, wherein the center frequency of the second passband is less than or equal to twice the center frequency of the first passband.

6. The multiplexer according to claim 1, wherein the piezoelectric substrate is a single crystal piezoelectric substrate including lithium niobate.

7. The multiplexer according to claim 1, wherein the piezoelectric substrate includes:
a piezoelectric layer including a first main surface and a second main surface, which face each other;
a support substrate on a side of the piezoelectric layer where the second main surface is located;
a low-acoustic-velocity layer between the piezoelectric layer and the support substrate and having a bulk wave acoustic velocity lower than a bulk wave acoustic velocity of the support substrate; and
a high-acoustic-velocity layer between the low-acoustic-velocity layer and the support substrate and having a bulk wave acoustic velocity higher than a bulk wave acoustic velocity of the low-acoustic-velocity layer.

8. The multiplexer according to claim 1, wherein the first passband includes at least one of band n75 and band n76 for 5G-NR.

9. The multiplexer according to claim 1, wherein the second passband is band B1, band B3, or band B7 for LTE, or band n1, n3, or n7 for 5G-NR.

10. The multiplexer according to claim 1, wherein the acoustic wave filter is a ladder bandpass filter or includes longitudinally coupled resonators.

11. The multiplexer according to claim 1, wherein the acoustic wave filter is a ladder filter including one or more series arm resonators and one or more parallel arm resonators.

12. The multiplexer according to claim 1, wherein the first filter is an acoustic wave filter, an LC filter, or a dielectric filter.

13. The multiplexer according to claim 1, further comprising a second filter and a third filter connected to the common terminal and each being an acoustic wave filter, an LC filter, or a dielectric filter.

14. The multiplexer according to claim 1, further comprising reflection electrodes on both side of the IDT electrode.

15. The multiplexer according to claim 1, further comprising a dielectric layer covering the insulating layer.

16. The multiplexer according to claim 1, wherein the piezoelectric substrate is a single-crystal piezoelectric substrate including lithium niobate, lithium tantalate, quartz or potassium nitride, or the piezoelectric substrate includes a piezoelectric layer, a low-acoustic-velocity layer, a high-acoustic-velocity layer, and a support substrate.

17. The multiplexer according to claim 1, wherein the center frequency fc2 of the second passband is less than or equal to at least about 2.0 times a center frequency fc1 of the first passband.

18. A communication device comprising the multiplexer according to claim 1.

19. The communication device according to claim 18, wherein the communication device is a mobile phone.

20. The communication device according to claim 18, further comprising a front end module including the multiplexer.
